(19) United States
(12) Patent Application Publication
(10) Pub. No.: US 2024/0371913 A1
(43) Pub. Date: Nov. 7, 2024

(54) LIGHT-EMITTING DIODE AND MANUFACTURING METHOD, LIGHT-EMITTING SUBSTRATE, BACKLIGHT MODULE, AND DISPLAY DEVICE

(71) Applicant: BOE TECHNOLOGY GROUP CO., LTD., Beijing (CN)

(72) Inventors: Yingtao WANG, Beijing (CN); Qian JIA, Beijing (CN); Tingting ZHOU, Beijing (CN); Xuefei SUN, Beijing (CN); Jaegeon YOU, Beijing (CN); Haokun LI, Beijing (CN)

(73) Assignee: BOE TECHNOLOGY GROUP CO., LTD., Beijing (CN)

(21) Appl. No.: 18/772,288

(22) Filed: Jul. 15, 2024

Related U.S. Application Data
(63) Continuation of application No. PCT/CN2023/082578, filed on Mar. 20, 2023.

(51) Int. Cl. H01L 27/15; G02F 1/13357; H01L 33/46; H01L 33/62

(52) U.S. Cl. CPC H01L 27/15; G02F 1/133603; H01L 33/46; H01L 33/62

(57) ABSTRACT

A light-emitting diode includes a base and light-emitting devices including a first light-emitting device, a second light-emitting device, and a third light-emitting device. The area of the first light-emitting device, the area of the second light-emitting device, and the area of the third light-emitting device decrease in order. Each light-emitting device includes a light-emitting stacked layer. In two adjacent light-emitting devices, at least one light-emitting device further includes a first reflective layer provided between a light-emitting stacked layer of the light-emitting device to which the first reflective layer belongs and another light-emitting device. The first reflective layer covers a first region and exposes at least a portion of a second region, the first region being a region where the two adjacent light-emitting devices overlap with each other, and the second region being a region where the two adjacent light-emitting devices are non-overlapping with each other.

### CROSS-REFERENCE TO RELATED APPLICATION

This application is a Bypass Continuation Application of International Patent Application No. PCT/CN2023/082578 filed on Mar. 20, 2023, which is incorporated herein by reference in its entirety.

### TECHNICAL FIELD

The present disclosure relates to the field of display technologies, and in particular, to a light-emitting diode and manufacturing method, a light-emitting substrate, a backlight module, and a display device.

### BACKGROUND

With the development of light-emitting diode technologies, backlight sources using light-emitting diodes (LEDs) with sub-millimeter scale and even micro(mini)-meter scale have been widely used. As a result, a picture contrast of products which utilize these backlight sources, such as liquid crystal displays (LCDs), not only reaches the level of organic light-emitting diode (OLED) display products, but also retains technological advantages of liquid crystal displays, thereby enhancing the display effect of the picture and providing the user with a high-quality visual experience.

### SUMMARY

In another aspect, a light-emitting diode is provided. The light-emitting diode includes a base and a plurality of light-emitting devices. The plurality of light-emitting devices include a first light-emitting device, a second light-emitting device, and a third light-emitting device that are stacked on the base in sequence. An area of the first light-emitting device is greater than an area of the second light-emitting device, and the area of the second light-emitting device is greater than an area of the third light-emitting device. A light-emitting color of the first light-emitting device, a light-emitting color of the second light-emitting device, and a light-emitting color of the third light-emitting device are three primary colors.

Each of the plurality of light-emitting devices includes a light-emitting stacked layer. In two adjacent light-emitting devices of the plurality of light-emitting devices, at least one light-emitting device further includes a first reflective layer, where the first reflective layer is provided between a light-emitting stacked layer of the light-emitting device to which the first reflective layer belongs and another light-emitting device, and the first reflective layer covers a first region and exposes at least a portion of a second region, the first region being a region where the two adjacent light-emitting devices overlap with each other, and the second region being a region where the two adjacent light-emitting devices are non-overlapping with each other.

In some embodiments, the at least one light-emitting device in the two adjacent light-emitting devices includes the first light-emitting device and the third light-emitting device; the first light-emitting device includes a first reflective layer, the first reflective layer being provided on a side of a light-emitting stacked layer of the first light-emitting device away from the base; and the third light-emitting device includes another first reflective layer, the first reflective layer being provided on a side of a light-emitting stacked layer of the third light-emitting device proximate to the base.

In some embodiments, the at least one light-emitting device in the two adjacent light-emitting devices includes the second light-emitting device; the second light-emitting device includes two first reflective layers, the two first reflective layers being provided on two sides opposite to each other of a light-emitting stacked layers of the second light-emitting device.

In some embodiments, the first reflective layer includes a distributed Bragg reflective film layer, the distributed Bragg reflective film layer including a plurality of first medium layers and a plurality of second medium layers. The plurality of first medium layers and the plurality of second medium layers are alternately stacked; and a difference between a refractive index of the first medium layers and a refractive index of the second medium layers is greater than or equal to 0.3.

In some embodiments, the refractive index of the first medium layers is in a range of 1.8 to 2.4, inclusive; and the refractive index of the second medium layers is in a range of 1.2 to 1.8, inclusive.

In some embodiments, the first reflective layer includes a metal reflective layer, a reflectivity of the metal reflective layer being greater than or equal to 85%.

In some embodiments, a material of the metal reflective layer includes at least one of aluminum, silver, copper, or platinum.

In some embodiments, of a surface of the first reflective layer proximate to the base or a surface of the first reflective layer away from the base, at least one has surface roughness in a range of 10 nm to 100 nm, inclusive.

In some embodiments, the first light-emitting device further includes: a second reflective layer provided between a light-emitting stacked layer of the first light-emitting device and the base, where an orthographic projection of the light-emitting stacked layer of the first light-emitting device on the base substantially coincides with an orthographic projection of the second reflective layer on the base, or lies within a range of the orthographic projection of the second reflective layer on the base.

In some embodiments, a material of the second reflective layer is same as a material of the first reflective layer.

In some embodiments, the light-emitting stacked layer includes a first semiconductor layer, a light-emitting layer, and a second semiconductor layer. The light-emitting layer is provided on a side of the first semiconductor layer, where an area of the light-emitting layer is less than an area of the first semiconductor layer, and an orthographic projection of the light-emitting layer on the base lies within a range of an orthographic projection of the first the semiconductor layer is on the base. The second semiconductor layer is provided on a side of the light-emitting layer away from the first semiconductor layer, where an orthographic projection of the second semiconductor layer on the base substantially coincides an orthographic projection of the light-emitting layer on the base.

In some embodiments, the first semiconductor layer includes a first portion and a second portion, the first portion being a portion of the first semiconductor layer that is overlapped with the light-emitting layer, and the second portion being a portion of the first semiconductor layer that is non-overlapping with the light-emitting layer.

The light-emitting substrate further includes: a plurality of first bonding pads, a plurality of second bonding pads, a plurality of first transfer electrodes, a plurality of second transfer electrodes, and a plurality of conductive lines. The plurality of first bonding pads are provided on the base. The plurality of second bonding pads are provided on the base. A first transfer electrode of the plurality of first transfer electrodes is provided on a second semiconductor layer of a light-emitting device of the plurality of light-emitting devices. A second transfer electrode of the plurality of second transfer electrodes is provided on a second portion of a first semiconductor layer of the light-emitting device of the plurality of light-emitting devices. The plurality of conductive lines include anode conductive lines and cathode conductive lines. Of an anode conductive line of the anode conductive lines, one end is connected to a first bonding pad of the plurality of first bonding pads, and an other end is connected to the first transfer electrode; and of a cathode conductive line of the cathode conductive lines, one end is connected to a second bonding pad of the plurality of second bonding pads, and an other end is connected to the second transfer electrode.

In some embodiments, orthographic projections of the plurality of conductive lines on the base are staggered. The light-emitting diode further includes a first conductive layer and a first barrier layer. The plurality of conductive lines are located in the first conductive layer. The first barrier layer is provided between the first conductive layer and the plurality of light-emitting devices, and the first barrier layer exposing the first transfer electrodes and the second transfer electrodes.

In some embodiments, the first bonding pads, the first transfer electrodes, the second bonding pads, and the second transfer electrodes are arranged along a same direction, and the plurality of conductive lines extend along the same direction. The light-emitting diode further includes a second conductive layer, a third conductive layer, a fourth conductive layer, a second barrier layer, a third barrier layer, and a fourth barrier layer.

Conductive lines connected to the first light-emitting device are located in the second conductive layer. Conductive lines connected to the second light-emitting device are located in the third conductive layer. Conductive lines connected to the third light-emitting device are located in the fourth conductive layer. The second barrier layer is provided between the second conductive layer and the plurality of light-emitting devices, and the second barrier layer expose the first transfer electrodes and the second transfer electrodes. The third barrier layer is provided between the second conductive layer and the third conductive layer, and the third barrier layer expose first transfer electrodes and second transfer electrodes that are located on the second light-emitting device and the third light-emitting device. The fourth barrier layer is provided between the third conductive layer and the fourth conductive layer, and the fourth barrier layer expose a first transfer electrode and a second transfer electrode that are located on the third light-emitting device.

In some embodiments, a boundary of an orthographic projection of the first light-emitting device on the base, a boundary of an orthographic projection of the second light-emitting device on the base, and a boundary of an orthographic projection of the third light-emitting device on the base are in a same shape; and the boundary of the orthographic projection of the first light-emitting device on the base and the boundary of the orthographic projection of the second light-emitting device on the base have a gap therebetween; and the boundary of the orthographic projection of the second light-emitting device on the base and the boundary of the orthographic projection of the third light-emitting device on the base have another gap therebetween.

In some embodiments, the orthographic projection of the first light-emitting device on the base, the orthographic projection of the second light-emitting device on the base, and the orthographic projection of the third light-emitting device on the base are each substantially in a shape of a circle or a polygon.

In some embodiments, a geometric center of the orthographic projection of the first light-emitting device on the base, a geometric center of the orthographic projection of the second light-emitting device on the base, and a geometric center of the orthographic projection of the third light-emitting device on the base substantially coincide.

In some embodiments, the light-emitting color of the first light-emitting device is red; and the light-emitting color of one of the second light-emitting device and the third light-emitting device is blue, and the light-emitting color of the other is green.

In another aspect, a manufacturing method for a light-emitting diode is provided. The manufacturing method includes: providing a base; forming a first light-emitting device, a second light-emitting device, and a third light-emitting device, an area of the first light-emitting device being greater than an area of the second light-emitting device, and the area of the second light-emitting device being greater than an area of the third light-emitting device; and transferring the first light-emitting device, the second light-emitting device, and the third light-emitting device to the base in sequence, the first light-emitting device being provided on the base, the second light-emitting device being provided on a side of the first light-emitting device away from the base, and the third light-emitting device being provided on a side of the second light-emitting device away from the base. Each of the plurality of light-emitting devices includes a light-emitting stacked layer. In two adjacent light-emitting devices of the plurality of light-emitting devices, at least one light-emitting device further includes a first reflective layer, where the first reflective layer is provided between a light-emitting stacked layer of the light-emitting device to which the first reflective layer belongs and another light-emitting device, and the first reflective layer covers a first region and exposes at least a portion of a second region, the first region being a region where the two adjacent light-emitting devices overlap with each other, and the second region being a region where the two adjacent light-emitting devices are non-overlapping with each other.

In yet another aspect, a light-emitting substrate is provided. The light-emitting substrate includes an array substrate, and the light-emitting diode as described in any of the above embodiments, the light-emitting diode being provided on the array substrate.

In still another aspect, a backlight module is provided. The backlight module includes the light-emitting substrate as described in any of the above embodiments, and a plurality of optical film sheets. The light-emitting substrate has a light exit side and a non-light exit side opposite to each other. The plurality of optical film sheets are provided on the light exit side of the light-emitting substrate.

In still yet another aspect, a display device is provided. The display device includes the backlight module as described in any of the above embodiments, and a display panel.

The display panel is provided on a side, away from the light-emitting substrate, of the plurality of optical film sheets in the backlight module.

### BRIEF DESCRIPTION OF THE DRAWINGS

In order to describe technical solutions in the present disclosure more clearly, the accompanying drawings to be used in some embodiments of the present disclosure will be introduced briefly; obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display device, in accordance with some embodiments;

FIG. 2 is a structural diagram of another display device, in accordance with some embodiments;

FIG. 3 is a sectional view of a display device, in accordance with some embodiments;

FIG. 4 is a structural diagram of a display panel, in accordance with some embodiments;

FIG. 5 is a structural diagram of another display panel, in accordance with some embodiments;

FIG. 6 is a structural diagram of a light-emitting substrate, in accordance with some embodiments;

FIG. 7 is a structural diagram of another light-emitting substrate, in accordance with some embodiments;

FIG. 8 is a top view of a light-emitting diode, in accordance with some embodiments;

FIG. 9 is a top view of another light-emitting diode, in accordance with some embodiments;

FIG. 10 is a top view of yet another light-emitting diode, in accordance with some embodiments;

FIG. 11 is a top view of still another light-emitting diode, in accordance with some embodiments;

FIG. 12 is a sectional view taken along the section line A-A′ in FIG. 9 or FIG. 11;

FIG. 13 is another sectional view taken along the section line A-A′ in FIG. 9 or FIG. 11;

FIG. 14 is yet another sectional view taken along the section line A-A′ in FIG. 9 or FIG. 11;

FIG. 15 is a sectional view taken along the section line B-B′ in FIG. 8 or FIG. 10;

FIG. 16 is a sectional view taken along the section line C-C′ in FIG. 8 or FIG. 10;

FIG. 17 is a sectional view taken along the section line D-D′ in FIG. 8 or FIG. 10;

FIG. 18 is a structural diagram of a first light-emitting device, in accordance with some embodiments;

FIG. 19 is a structural diagram of another first light-emitting device, in accordance with some embodiments;

FIG. 20 is a structural diagram of a second light-emitting device, in accordance with some embodiments;

FIG. 21 is a structural diagram of another second light-emitting device, in accordance with some embodiments;

FIG. 22 is a structural diagram of a third light-emitting device, in accordance with some embodiments;

FIG. 23 is a structural diagram of another third light-emitting device, in accordance with some embodiments;

FIG. 24 is a structural diagram of a reflective layer, in accordance with some embodiments; and

FIGS. 25 and 26 are flowcharts of a manufacturing method for a light-emitting diode, in accordance with some embodiments.

### DETAILED DESCRIPTION

The technical solutions in embodiments of the present disclosure will be described clearly and completely with reference to the accompanying drawings; obviously, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, specific features, structures, materials, or characteristics described herein may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, the features defined with “first” and “second” may explicitly or implicitly include one or more of the features. In the description of the embodiments of the present disclosure, the term “a plurality of (multiple)” means two or more unless otherwise specified.

Some embodiments may be described using the terms “coupled”, “connected” and their derivatives. The term “connection” should be understood in a broad sense. For example, “connection” can be a fixed connection, a detachable connection, or an integrated connection; it can be a direct connection or an indirect connection through an intermediate medium. The term “coupled” indicates, for example, that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” used herein means an open and inclusive expression, which does not exclude devices that are applicable to or configured to perform additional tasks or steps.

In addition, the phrase “based on” used is meant to be open and inclusive, since a process, step, calculation, or other action that is “based on” one or more of the stated conditions or values may, in practice, be based on additional conditions or values exceeding those stated.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The terms such as “parallel”, “perpendicular” and “equal” as used herein include a stated case and a case similar to the stated case within an acceptable range of deviation determined by a person of ordinary skill in the art, considering measurement in question and errors associated with measurement of a particular quantity (i.e., limitations of a measurement system). The term “equal” includes absolute equality and approximate equality, and an acceptable range of deviation of approximate equality may be, for example, that a difference between two equals is less than or equal to 5% of any one of the two equals.

It will be understood that, in a case that a layer or element is referred to be on another layer or substrate, it may be that the layer or element is directly on the another layer or substrate, or it may be that there is an intermediate layer between the layer or element and the another layer or substrate.

Exemplary embodiments are described herein with reference to sectional views and/or plan views as idealized exemplary drawings. In the accompanying drawings, thicknesses of layers and areas of regions are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

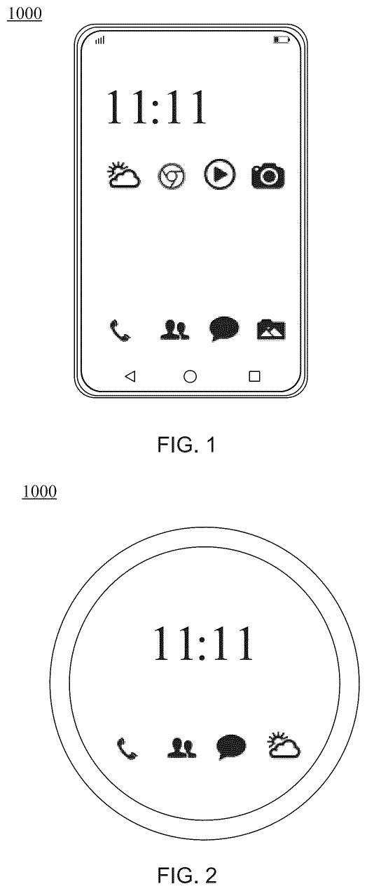

As shown in FIGS. 1 and 2, some embodiments of the present disclosure provide a display device 1000. The display device 1000 may be any device that can display an image whether in motion (e.g., video) or stationary (e.g., a still image), and whether textual or pictorial.

By way of example, referring to FIGS. 1 and 2, the display device 1000 may be any product or component having a display function, such as a television, a notebook computer, a tablet computer, a mobile phone, a personal digital assistant (PDA), a navigator, a wearable device, a virtual reality (VR) device, or the like.

In some embodiments, the display device 1000 may be a liquid crystal display (LCD) device.

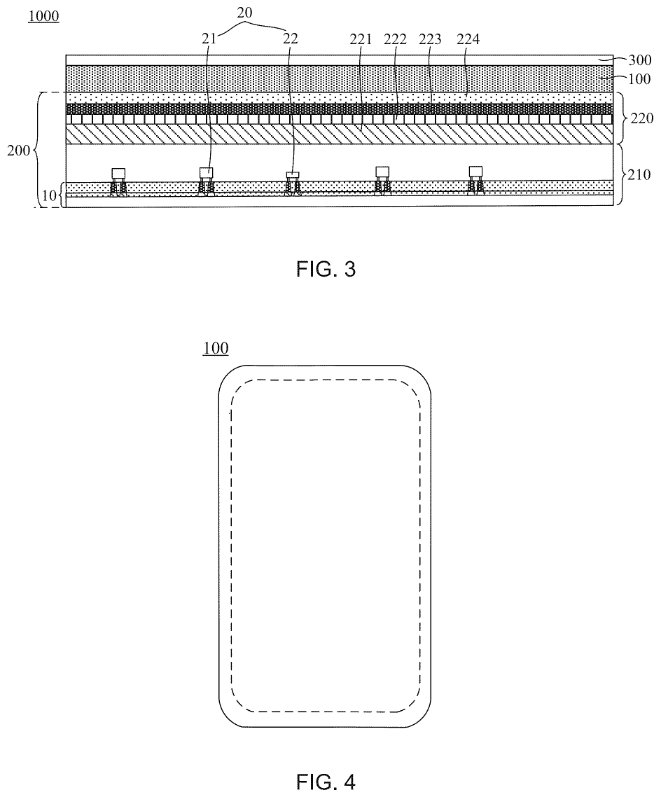

By way of example, referring to FIGS. 3, 4 and 5, the display device 1000 includes a display panel 100.

As shown in FIG. 3, the display panel 100 includes a light exit side and a non-light exit side provided opposite to each other. The light exit side refers to a side of the display panel 100 for displaying pictures (an upper side of the display panel 100 in FIG. 3), and the non-light exit side refers to the other side opposite to the light exit side (a lower side of the display panel 100 in FIG. 3).

It can be understood that depending on different application scenarios, a shape of a surface on the light exit side of the display panel 100 is not unique.

As shown in FIG. 1, the display device 1000 may be a portable display product; for example, the display device 1000 may be a mobile phone as shown in FIG. 1.

In this case, as shown in FIG. 4, the shape of the surface on the light exit side of the display panel 100 is substantially in a shape of a rectangle.

The term “substantially in a shape of a rectangle” herein means that a described object is in a shape of a rectangle as a whole, but is not limited to a standard rectangle. That is, “rectangle” here includes not only a standard rectangle but also a shape similar to a rectangle. For example, the long and short sides of the rectangle are curved at each intersecting position (i.e., at each corner), i.e., the corners are smooth and the shape is a rounded rectangle. For example, some of segments in the long and short sides of the rectangle are curved.

As another example, referring to FIG. 2, the display device 1000 may be a wearable device; for example, the display device 1000 may be a round watch as shown in FIG. 2.

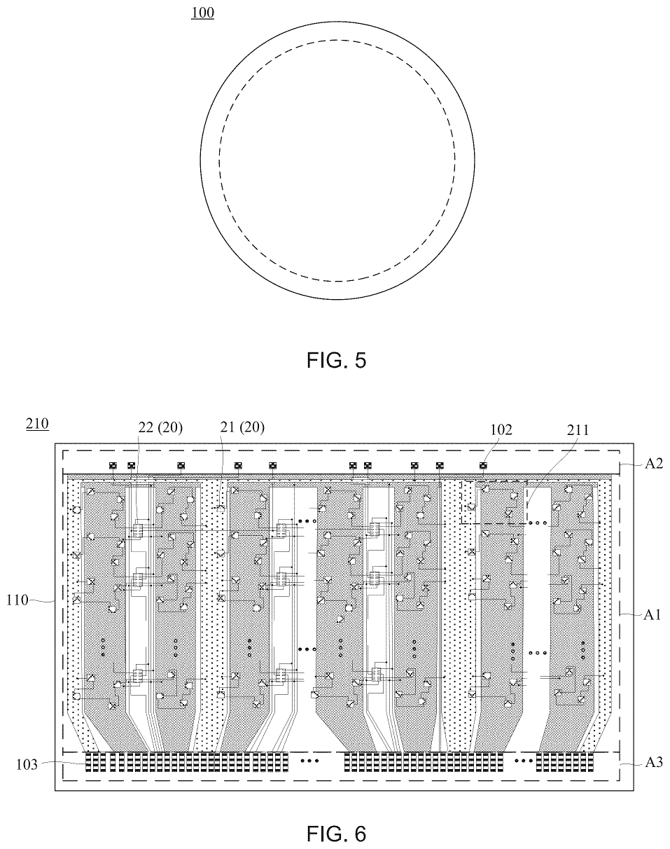

In this case, as shown in FIG. 5, the shape of the surface on the light exit side of the display panel 100 is substantially in a shape of a circle or ellipse.

The term “substantially in a shape of a circle or ellipse” herein means that a described object is in a shape of a circle or ellipse as a whole, but is not limited to a standard circle or ellipse. That is, “circle or ellipse” here includes not only a standard circle or ellipse but also a shape similar to a circle or ellipse.

Some embodiments of the present disclosure are hereinafter schematically illustrated by taking such a display device 1000 as an example, i.e., the display device 1000 is a portable display product in which a shape of a surface on a light exit side of a display panel 100 in the portable display product is substantially in a shape of a rectangle, but the embodiments of the present disclosure are not limited to this.

By way of example, referring to FIG. 3, the display device 1000 further includes a backlight module 200 and a transparent cover plate 300.

As shown in FIG. 3, the transparent cover plate 300 is provided on the light exit side of the display panel 100, which is used to protect the display panel 100. By way of example, a material used for the transparent cover plate 300 may be one selected from rigid materials, such as glass, quartz, plastic, or the like; alternatively, the material used for the transparent cover plate 300 may be one selected from flexible materials, such as polymer resin.

As shown in FIG. 3, the backlight module 200 is provided on the non-light exit side of the display panel 100, which is used to provide a light source for the display panel 100.

In some examples, please continue to refer to FIG. 3, the backlight module 200 includes a light-emitting substrate 210 and a plurality of optical film sheets 220.

As shown in FIG. 3, the light-emitting substrate 210 has a light-emitting side and a non-light-emitting side arranged opposite to each other, in which the light-emitting side is a side of the light-emitting substrate 210 that provides the light source (an upper side of the light-emitting substrate 210 in FIG. 3), and the non-light-emitting side is the other side opposite to the light-emitting side (a lower side of the light-emitting substrate 210 in FIG. 3).

It should be understood that a shape of a surface on the light-emitting side of the light-emitting substrate 210 should be substantially the same as the shape of the surface on the light exit side of the display panel 100. That is, in a case where the shape of the surface on the light exit side of the display panel 100 is substantially in a shape of a rectangle, the shape of the surface on the light-emitting side of the light-emitting substrate 210 is also substantially in a shape of a rectangle; and in a case where the shape of the surface on the light exit side of the display panel 100 is substantially in the shape of a circle or ellipse, the shape of the surface on the light-emitting side of the light-emitting substrate 210 is also substantially in a shape of a circle or ellipse.

As shown in FIG. 3, the plurality of optical film sheets 220 are provided on the light-emitting side of the light-emitting substrate 210.

Here, the light-emitting substrate 210 can emit white light directly, and the white light is directed to the display panel 100 after uniform light processing by the plurality of optical film sheets 220; alternatively, the light-emitting substrate 210 can emit light of another color (e.g., blue light), which is then directed to the display panel 100 after color conversion and uniform light processing by the plurality of optical film sheets 220.

By way of example, referring to FIG. 3, the plurality of optical film sheets 220 include a diffusion plate 221, a quantum dot film 222, a diffusion sheet 223, and a composite film 224 which are arranged sequentially along a direction perpendicular to the light-emitting substrate 210 and away from the light-emitting substrate 210.

The diffusion plate 221 is capable of blurring (i.e., diffusing) light emitted from the light-emitting substrate 210, and providing support for the quantum dot film 222, the diffusion sheet 223, and the composite film 224. The quantum dot film 222 can emit white light upon excitation of the light of a certain color emitted by the light-emitting substrate 210, i.e., the light is converted into white light to improve the utilization of light energy of the light-emitting substrate 210. The diffusion sheet 223 is capable of homogenizing the light passing through the diffusion sheet 223. The composite film 224 is capable of enhancing the light output efficiency of the backlight module 200 and improving the display brightness of the display device 1000.

It will be noted that the composite film 224 may include a brightness enhancement film (BEF) and a reflective polarization brightness enhancement film (i.e., dual brightness enhancement film, DBEF for short), utilizing the principles of total reflection, refraction, and polarization to enhance the light flux in a certain angular range, so as to enhance the brightness of the display device 1000.

For example, the light-emitting substrate 210 emits blue light along the direction away from the light-emitting substrate 210. The quantum dot film 222 may have a red quantum dot material, a green quantum dot material, and a transparent material. A portion of the blue light emitted by the light-emitting substrate 210 is converted to red light after passing through the red quantum dot material; another portion of the blue light is converted to green light after passing through the green quantum dot material; and the remaining portion of the blue light can pass through the transparent material directly; and then the blue light, the red light, and the green light are mixed and superimposed with a certain proportion to be presented as white light. Ultimately, the diffusion plate 221 and the diffusion sheet 223 are capable of mixing the white light, so as to alleviate the light shadow produced by the light-emitting substrate 210 and improve the display picture quality of the display device 1000.

In some embodiments, referring to FIG. 6, the light-emitting substrate 210 has a light-emitting region A1 and a test region A2 located on at least one side of the light-emitting region A1.

By way of example, as shown in FIG. 6, the test region A2 is located on one side of the light-emitting region A1; moreover, the light-emitting substrate 210 further has a bonding region A3, and the test region A2 and the bonding region A3 are located on opposite sides of the light-emitting region A1, respectively.

It will be noted that the light-emitting region A1 is configured to provide light-emitting circuits therein, the light-emitting circuits may, for example, include the electronic components 20 as will be addressed below; the test region A2 is configured to provide test circuits therein, the test circuits may, for example, include test electrodes 102; and the bonding region A3 is configured to provide bonding circuits therein, the bonding circuits may, for example, include bonding electrodes 103.

The light-emitting substrate 210 includes an array substrate 101 and electronic components 20. The electronic components 20 are provided on the array substrate 101 and located in the light-emitting region A1.

By way of example, referring to FIG. 3, the electronic components 20 may be electrically connected to bonding pads on the array substrate 101 to be fixed on the array substrate 101.

Referring to FIGS. 3 and 6, the electronic components 20 may include light-emitting diodes 21 and/or microchips 22.

As shown in FIG. 3, the microchips 22 may include sensing chips and driving chips, in which the sensing chip may be, for example, a light-sensitive sensor chip or a thermo-sensitive sensor chip, and the driving chip is used to provide a driving signal to a light-emitting diode 21.

As shown in FIG. 3, the light-emitting diodes 21 may include Micro LEDs and Mini LEDs. The Micro LEDs have a size (e.g., length) of less than 50 μm, e.g., in a range of 10 μm to 50 μm, inclusive. The Mini LEDs have a size (e.g., length) in a range of 50 μm to 150 μm, inclusive, e.g., 80 μm to 120 μm, inclusive.

In the related art, a variety of light-emitting devices of different colors are stacked to form a single light-emitting diode, in order to reduce the technical difficulty of transferring a variety of monochromatic light-emitting diodes separately in bulk. However, light emitted upward from a light-emitting device located on the lower side cannot pass through a light-emitting device on the upper side thereof, resulting in a portion of the light being unable to be emitted, and low light output efficiency; alternatively, the light emitted upward from the light-emitting device located on the lower side passes directly through the light-emitting device on the upper side thereof, resulting in the problem of crosstalk color.

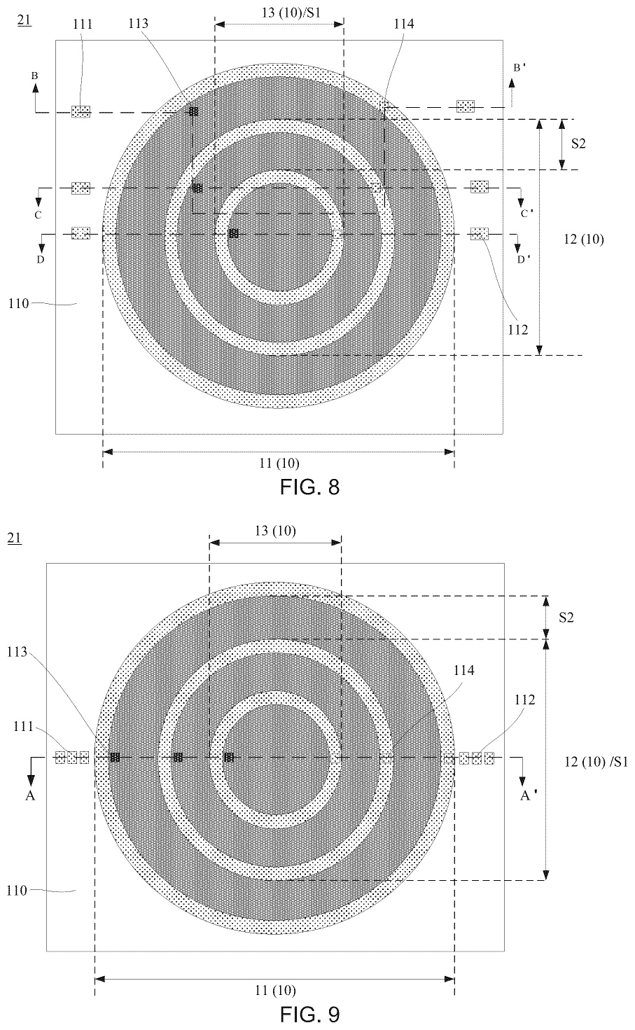

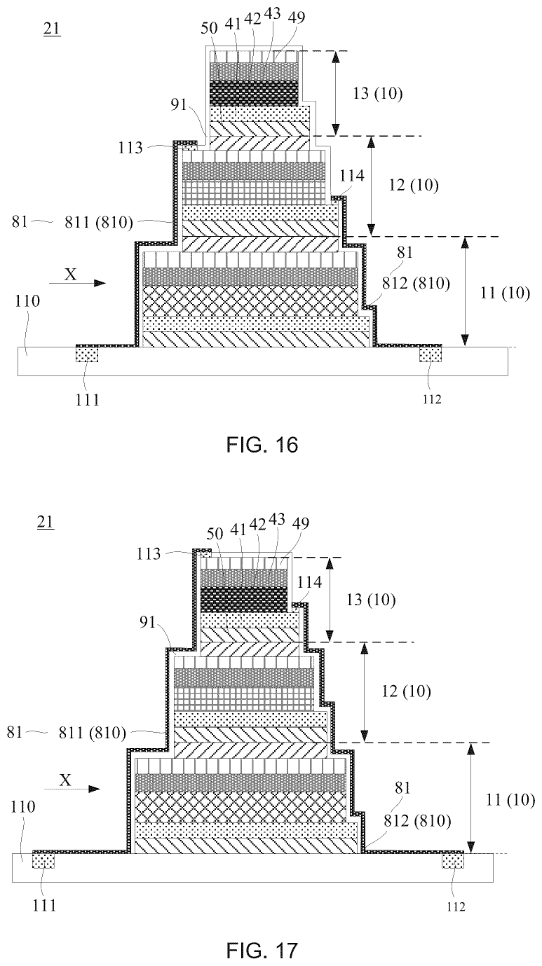

In light of this, referring to FIGS. 8 to 17, some embodiments of the present disclosure provide a light-emitting diode 21, which includes a base 110 and a plurality of light-emitting devices 10 stacked on the base 110.

In some embodiments, as shown in FIGS. 9, 10 and 12, the plurality of light-emitting devices 10 include a first light-emitting device 11, a second light-emitting device 12, and a third light-emitting device 13 that are stacked on the base 110 in sequence, where an area of the first light-emitting device 11 is greater than an area of the second light-emitting device 12, and the area of the second light-emitting device 12 is greater than an area of the third light-emitting device 13.

Here, the area of any light-emitting device 10 addressed above may be understood as an area of an orthographic projection thereof on the base 110. That is, an orthographic projection of the third light-emitting device 13 on the base 110 lies within a range of an orthographic projection of the second light-emitting device 12 on the base 110, to enable light emitted by the second light-emitting device 12 to be emitted from a region beyond the third light-emitting device 13; and an orthographic projection of the second light-emitting device 12 on the base 110 lies within a range of an orthographic projection of the first light-emitting device 11 on the base 110, to enable light emitted by the first light-emitting device 11 to be emitted from a region beyond the second light-emitting device 12.

It will be noted that the base 110 may include a circuit located on a surface thereon or located therein, but is not limited thereto. The base 110 may include, for example, any of a glass base, a sapphire base, a silicon base, or a germanium base.

Here, the light-emitting color of any light-emitting device 10 addressed above may refer to the color of light emitted by this light-emitting device 10. A light-emitting color of the first light-emitting device 11, a light-emitting color of the second light-emitting device 12, and a light-emitting color of the third light-emitting device 13 are three primary colors, so as to achieve color display of the display device 1000 (refer to FIG. 1).

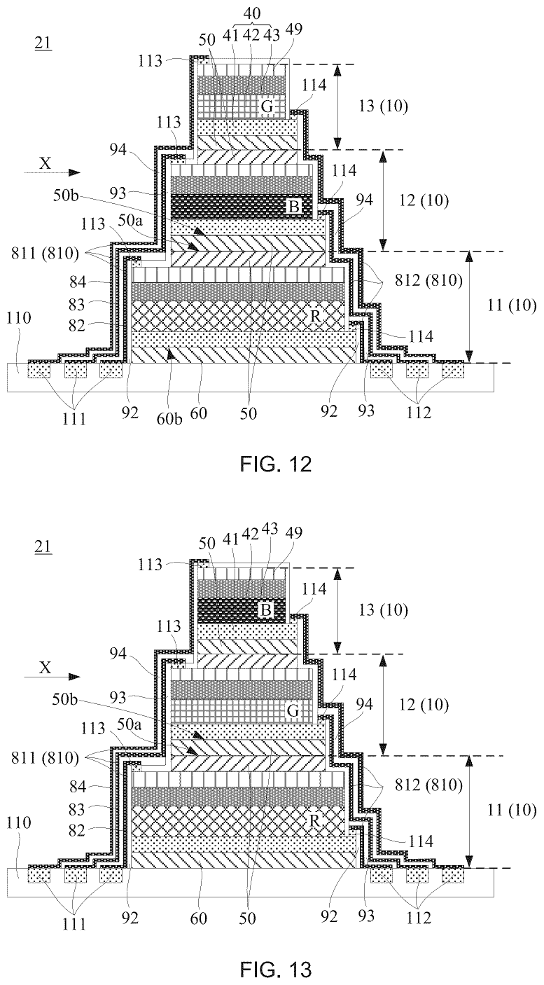

By way of example, referring to FIGS. 12 and 13, the light-emitting color of the first light-emitting device 11 is red; and the light-emitting color of one of the second light-emitting device 12 and the third light-emitting device 13 is blue, and the light-emitting color of the other is green.

It will be understood that a light-emitting device 10 with a light-emitting color of red has a poorer light-emitting efficiency, compared to a light-emitting device 10 with a light-emitting color of blue or green. In view of this, the first light-emitting device 11 with a light-emitting color of red is provided at the bottom, and has a larger light-emitting area, which can improve the light-emitting efficiency of the first light-emitting device 11 and enhance the light-emitting effect of the first light-emitting device 11.

For example, as shown in FIG. 12, the light-emitting color of the first light-emitting device 11 is red (with its light-emitting layer denoted as R), the light-emitting color of the second light-emitting device 12 is blue (with its light-emitting layer denoted as B), and the light-emitting color of the third light-emitting device 13 is green (with its light-emitting layer denoted as G).

As another example, as shown in FIG. 13, the light-emitting color of the first light-emitting device 11 is red (with its light-emitting layer denoted as R), the light-emitting color of the second light-emitting device 12 is green (with its light-emitting layer denoted as G), and the light-emitting color of the third light-emitting device 13 is blue (with its light-emitting layer denoted as B).

In some embodiments, referring to FIGS. 8 to 11, an outer contour (i.e., a boundary) of an orthographic projection of the first light-emitting device 11 on the base 110, an outer contour (i.e., a boundary) of an orthographic projection of the second light-emitting device 12 on the base 110, and an outer contour (i.e., a boundary) of an orthographic projection of the third light-emitting device 13 on the base 110 are in a same shape. Moreover, the boundary of the orthographic projection of the first light-emitting device 11 on the base 110 and the boundary of the orthographic projection of the second light-emitting device 12 on the base 110 have a gap therebetween; and the boundary of the orthographic projection of the second light-emitting device 12 on the base 110 and the boundary of the orthographic projection of the third light-emitting device 13 on the base 110 have another gap therebetween.

By way of example, as shown in FIGS. 8 to 11, the orthographic projection of the first light-emitting device 11 on the base 110, the orthographic projection of the second light-emitting device 12 on the base 110, and the orthographic projection of the third light-emitting device 13 on the base 110 are each substantially in a shape of a circle or a polygon.

For example, as shown in FIGS. 8 and 9, the orthographic projection of the first light-emitting device 11 on the base 110, the orthographic projection of the second light-emitting device 12 on the base 110, and the orthographic projection of the third light-emitting device 13 on the base 110 are each substantially in a shape of a circle.

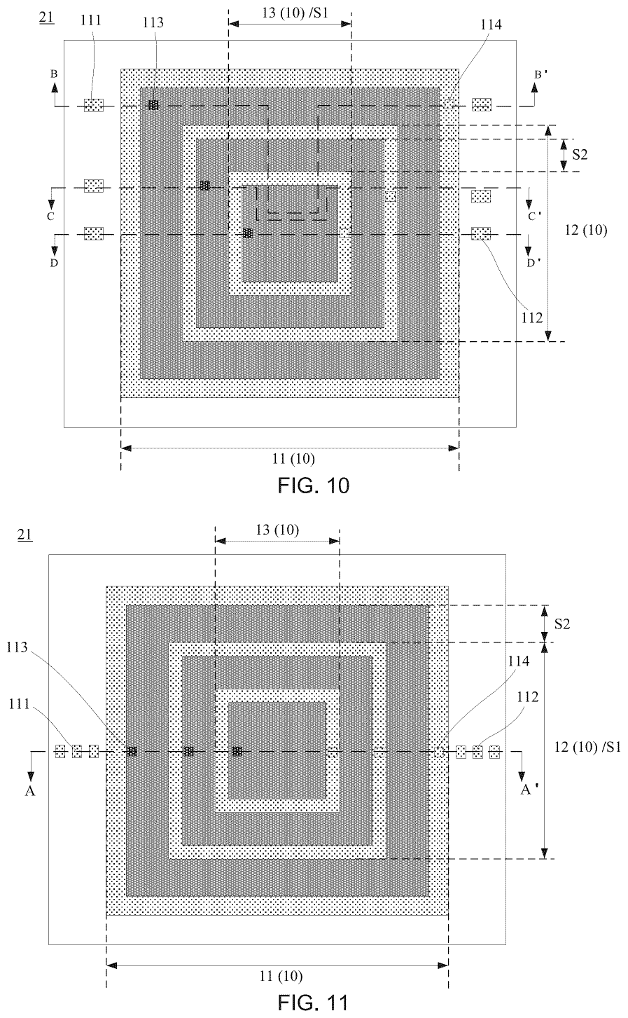

As another example, as shown in FIGS. 10 and 11, the orthographic projection of the first light-emitting device 11 on the base 110, the orthographic projection of the second light-emitting device 12 on the base 110, and the orthographic projection of the third light-emitting device 13 on the base 110 are each substantially in a shape of a rectangle.

On this basis, a geometric center of the orthographic projection of the first light-emitting device 11 on the base 110, a geometric center of the orthographic projection of the second light-emitting device 12 on the base 110, and a geometric center of the orthographic projection of the third light-emitting device 13 on the base 110 substantially coincide with each other. Arranged in this way, light emitted by a light-emitting device 10 located on the lower side can uniformly surround the outside of light emitted by a light-emitting device 10 located on the upper side, which is conducive to the uniformity of the light mixing of the plurality of light-emitting devices 10 and reduces the risk of the light-emitting diode 21 generating color deviation.

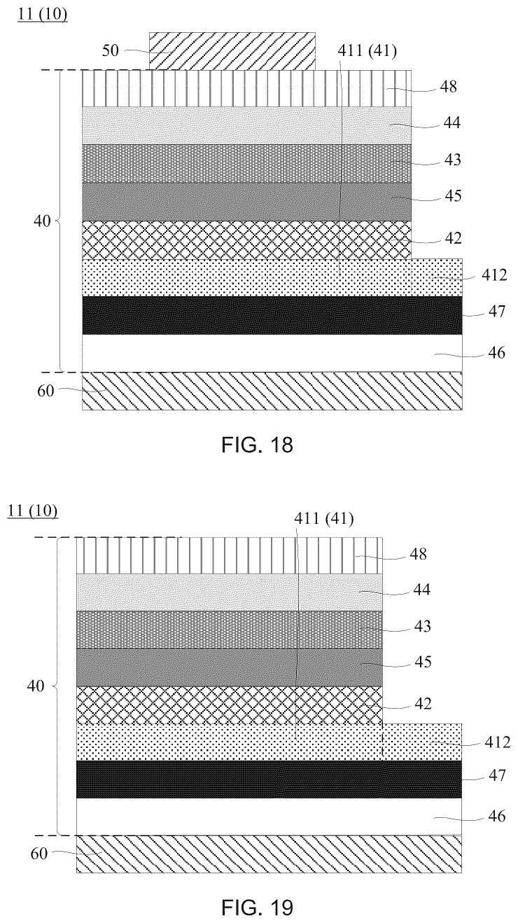

In some embodiments, referring to FIGS. 18 to 23, each light-emitting device 10 includes a light-emitting stacked layer 40. The light-emitting stacked layer 40 includes a first semiconductor layer 41, a light-emitting layer 42, and a second semiconductor layer 43. The light-emitting layer 42 is provided on a side of the first semiconductor layer 41, and the second semiconductor layer 43 is provided on a side of the light-emitting layer 42 away from the first semiconductor layer 41.

One of the first semiconductor layer 41 and the second semiconductor layer 43 is a P-type semiconductor layer and the other is an N-type semiconductor layer. The light-emitting layer 42 may be, for example, a multiple quantum well (MQW) layer.

In this case, when a voltage is applied to the light-emitting device 10, electrons in the N-type semiconductor layer will migrate toward the light-emitting layer 42 and enter into the light-emitting layer 42; at the same time, holes in the P-type semiconductor layer also migrate toward the light-emitting layer 42 and enter into the light-emitting layer 42. And then, the electrons that enter into the light-emitting layer 42 are compounded with the holes, thus generating spontaneous radiation light.

Some embodiments of the present disclosure are illustrated exemplarily below with the first semiconductor layer 41 being an N-type semiconductor layer and the second semiconductor layer 43 being a P-type semiconductor layer, but the embodiments of the present disclosure are not limited to this, and it is also possible to consider that the first semiconductor layer 41 is a P-type semiconductor layer and the second semiconductor layer 43 is an N-type semiconductor layer, as long as the same technical ideas are applied.

In some examples, referring to FIG. 18, the light-emitting stacked layer 40 may further include at least one of an electron transport layer (ETL), an electron injection layer (EIL), an electron blocking layer (EBL), a hole transport layer (HTL), a hole injection layer (HIL), and an electron blocking layer (EBL).

For example, as shown in FIG. 18, the light-emitting stacked layer 40 further includes an electron transport layer 44 and an electron blocking layer 45. The first semiconductor layer 41 is an N-type semiconductor layer, and the second semiconductor layer 43 is a P-type semiconductor layer. The electron transport layer 44 is provided on a side of the second semiconductor layer 43 away from the first semiconductor layer 41, and the electron blocking layer 45 is provided between the second semiconductor layer 43 and the light-emitting layer 42.

In some examples, as shown in FIG. 18, the light-emitting stacked layer 40 may further include an underlayer 46 and a buffer layer 47. The first semiconductor layer 41 is an N-type semiconductor layer, and the second semiconductor layer 43 is a P-type semiconductor layer. The buffer layer 47 is provided on a side of the first semiconductor layer 41 away from the second semiconductor layer 43, and the underlayer 46 is provided on a side of the buffer layer 47 away from the second semiconductor layer 43.

It will be noted that the underlayer 46 may include any one of a glass underlayer, a sapphire underlayer, a silicon underlayer, or a germanium underlayer, so as to facilitate the formation of the first semiconductor layer 41, the light-emitting layer 42, and the second semiconductor layer 43 which are stacked in sequence. A material of the buffer layer 47 may include at least one of silicon oxide, silicon nitride, and silicon nitride oxide. For example, the material of the buffer layer 47 is silicon nitride, to serve the purpose of providing a buffer when making patterns on the underlayer 46 as well as resisting water and oxygen erosion.

In some examples, referring to FIG. 18, the light-emitting stacked layer 40 may further include a first electrode and/or a second electrode. Of the first electrode and the second electrode, one is provided on a side of the first semiconductor layer 41 away from the second semiconductor layer 43, and the other is provided on a side of the second semiconductor layer 43 away from the first semiconductor layer 41.

In this way, the first electrode injects carriers (one of holes and electrons) into the first semiconductor layer 41, and the second electrode injects carriers (the other of holes and electrons) into the second semiconductor layer 43.

A material of the first electrode and a material of the second electrode described above each include a transparent metal oxide. Here, the transparent metal oxide refers to metal oxide having a light transmittance greater than or equal to 90%. In an example, the material of the first electrode and the material of the second electrode each include at least one of indium tin oxide, indium tin zinc oxide, indium gallium zinc oxide, indium tin zinc oxide, or indium gallium tin oxide.

For example, as shown in FIG. 18, the first semiconductor layer 41 is an N-type semiconductor layer, and the second semiconductor layer 43 is a P-type semiconductor layer. The light-emitting stacked layer 40 includes a first electrode 48, and the first electrode 48 is provided on a side of the second semiconductor layer 43 away from the first semiconductor layer 41.

On this basis, in two adjacent light-emitting devices 10, at least one light-emitting device 10 further includes a first reflective layer 50, and the first reflective layer 50 is provided between a light-emitting stacked layer 40 of the light-emitting device 10 to which the first reflective layer 50 belongs and the other light-emitting device 10, so as to reflect light from the light-emitting stacked layer 40.

In some examples, as shown in FIG. 24, the first reflective layer 50 includes a distributed Bragg reflective (DBR) film layer 51. The DBR film layer 51 includes a plurality of first medium layers 511 and a plurality of second medium layers 512, and the plurality of first medium layers 511 and the plurality of second medium layers 512 are alternately stacked.

Here, a difference between a refractive index of the first medium layer 511 and a refractive index of the second medium layer 512 is greater than or equal to 0.3.

By way of example, the refractive index of the first medium layer 511 is in a range of 1.8 to 2.4, inclusive. For example, the refractive index of the first medium layer 511 is any one of 1.8, 1.9, 2.0, 2.1, 2.2, 2.3, and 2.4.

By way of example, the refractive index of the second medium layer 512 is in a range of 1.2 to 1.8 inclusive. For example, the refractive index of the second medium layer 512 is any one of 1.2, 1.3, 1.4, 1.5, 1.6, 1.7, and 1.8.

In some other examples, the first reflective layer 50 includes a metal reflective layer, and a reflectivity of the metal reflective layer is greater than or equal to 85%.

By way of example, a material of the metal reflective layer includes at least one of aluminum, silver, copper, or platinum. For example, the material of the metal reflective layer is aluminum.

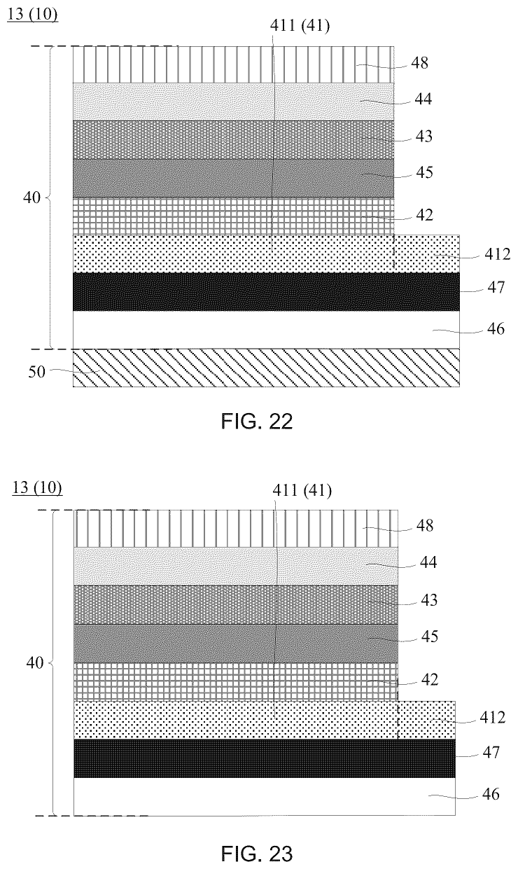

In some embodiments, as shown in FIG. 18, the first light-emitting device 11 includes a first reflective layer 50, and this first reflective layer 50 is provided on a side of the light-emitting stacked layer 40 of the first light-emitting device 11 away from the base 110 (the base 110 being not shown in FIG. 18). As shown in FIG. 21, the second light-emitting device 12 includes no first reflective layer 50. As shown in FIG. 22, the third light-emitting device 13 includes another first reflective layer 50, and this first reflective layer 50 is provided on a side of the light-emitting stacked layer 40 of the third light-emitting device 13 proximate to the base 110 (the base 110 being not shown in FIG. 22).

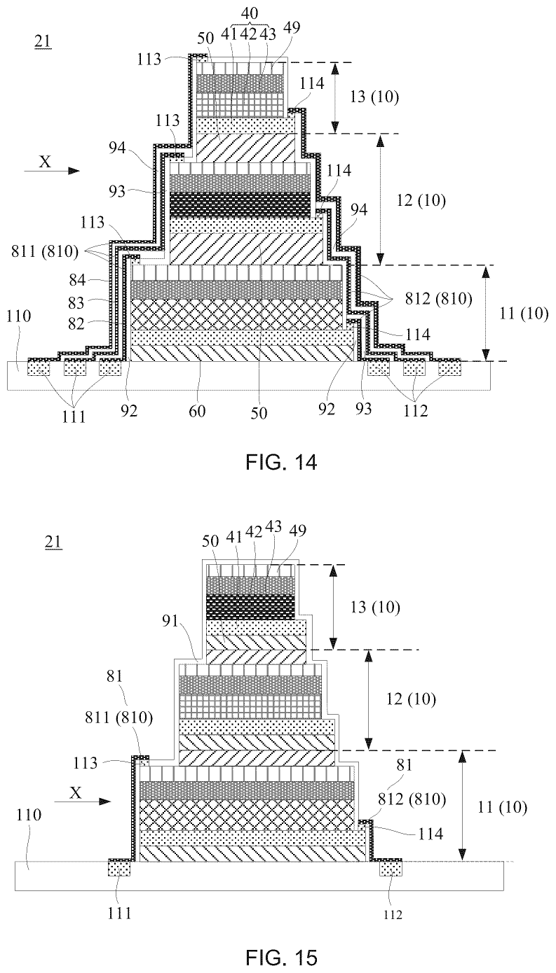

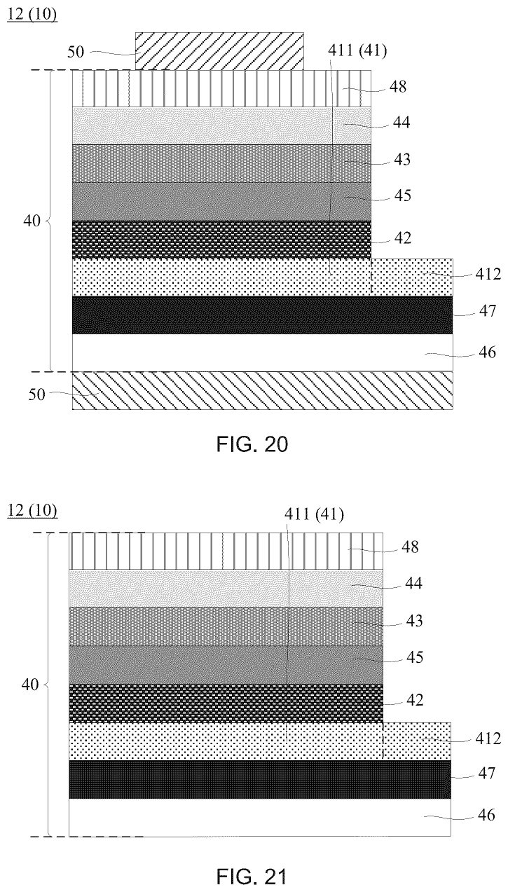

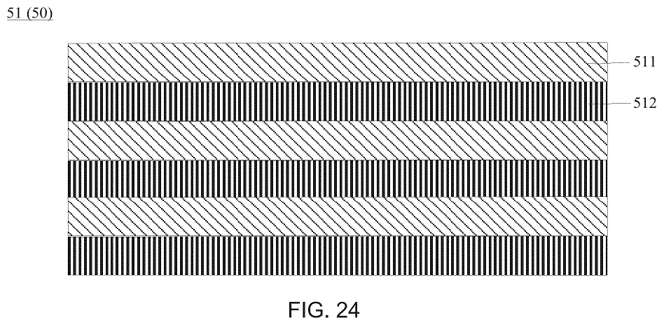

In some other embodiments, as shown in FIGS. 14 and 19, the first light-emitting device 11 includes no first reflective layer 50. As shown in FIGS. 14 and 23, the third light-emitting device 13 includes no first reflective layer 50. As shown in FIGS. 14 and 20, the second light-emitting device 12 includes two first reflective layers 50, and these two first reflective layers 50 are provided on opposite sides of the light-emitting stacked layer 40 in the second light-emitting device 12.

In yet some other embodiments, as shown in FIGS. 12 and 18, the first light-emitting device 11 includes a first reflective layer 50, and this first reflective layer 50 is provided on a side of the light-emitting stacked layer 40 of the first light-emitting device 11 away from the base 110. As shown in FIGS. 12 and 20, the second light-emitting device 12 includes two first reflective layers 50, and these two first reflective layers 50 are provided on opposite sides of the light-emitting stacked layer 40 in the second light-emitting device 12. As shown in FIGS. 12 and 22, the third light-emitting device 13 includes another first reflective layer 50, and this first reflective layer 50 is provided on a side of the light-emitting stacked layer 40 in the third light-emitting device 13 proximate the base 110.

In some examples, for two adjacent light-emitting devices 10 among the first light-emitting device 11, the second light-emitting device 12, and the third light-emitting device 13 in the embodiments addressed above, a first reflective layer 50 of a (e.g., each) light-emitting device 10, which is closer to the other light-emitting device 10 than a light-emitting stacked layer 40 thereof, is a metal-reflective layer. In this case, a light-emitting stacked layer 40 of a light-emitting device 10 located on the upper side of the two adjacent light-emitting devices 10 further includes an underlayer 46 and/or a buffer layer 47 to act as an insulating function.

Some embodiments of the present disclosure are schematically illustrated below taking the first light-emitting device 11 including a first reflective layer 50, the second light-emitting device 12 including two first reflective layers 50, and the third light-emitting device 13 including another first reflective layer 50, which are addressed above, as an example, but the embodiments of the present disclosure are not limited to this.

Referring to FIGS. 8 to 12, the first reflective layer 50 covers a first region S1 and exposes at least a portion of a second region S2. For example, as shown in FIGS. 8 to 12, the first reflective layer 50 covers the first region S1 and exposes the entire second region S2.

It will be noted that the first region S1 is a region where two adjacent light-emitting devices 10 overlap with each other, and the second region S2 is a region where two adjacent light-emitting devices 10 are non-overlapping with each other. The first region S1 and the second region S2 are shown in FIGS. 8 and 10 taking an example in which the two adjacent light-emitting devices 10 are the second light-emitting device 12 and the third light-emitting device 13, and the first region S1 and the second region S2 are shown in FIGS. 9 and 11 taking an example in which the two adjacent light-emitting devices 10 are the first light-emitting device 11 and the second light-emitting device 12.

As can be seen from the above, in the light-emitting diode 21 provided in the embodiments of the present disclosure, a portion of light emitted upwardly by a light-emitting device 10 located on the lower side can be reflected by a first reflective layer 50 on the upper side of this light-emitting device 10, and then emitted from a portion of this light-emitting device 10 that is not blocked by other light-emitting devices 10 on the upper side thereof, thus improving the light output efficiency and avoiding the generation of a problem of color crosstalk.

For example, as shown in FIGS. 9 and 12, light emitted from the second light-emitting device 12 toward the third light-emitting device 13 can be reflected by a first reflective layer 50 in the second light-emitting device 12 that is proximate to the third light-emitting device, and then be reflected by a first reflective layer 50 in the second light-emitting device 12 that is proximate to the first light-emitting device 11, so that a large proportion of the light can be emitted from a portion of the second light-emitting device 12 that is not blocked by the third light-emitting device 13, thereby improving the light output efficiency and avoiding the problem of color crosstalk.

As another example, as shown in FIGS. 9 and 12, light emitted from the first light-emitting device 11 toward the second light-emitting device 12 can be reflected by a first reflective layer 50 in the first light-emitting device 11 that is proximate to the second light-emitting device 12, so that a portion of the light can be emitted from a portion of the first light-emitting device 11 that is not blocked by the second light-emitting device 12, thereby improving the light output efficiency and avoiding the problem of color crosstalk.

In addition, as shown in FIG. 12, light emitted from the third light-emitting device 13 toward the second light-emitting device 12 can be reflected by a first reflective layer 50 in the third light-emitting device 13 that is proximate to the second light-emitting device 12, and directed out of the upper side of the third light-emitting device 13, thereby improving the light output efficiency.

On this basis, as shown in FIG. 12, the first light-emitting device 11 further includes a second reflective layer 60, and the second reflective layer 60 is provided between a light-emitting stacked layer 40 of the first light-emitting device 11 and the base 110. An orthographic projection of the light-emitting stacked layer 40 of the first light-emitting device 11 on the base 110 substantially coincides with an orthographic projection of the second reflective layer 60 on the base 110, or lies within a range of the orthographic projection of the second reflective layer 60 on the base 110.

In this case, light emitted from the first light-emitting device 11 toward the second light-emitting device 12 is reflected by the first reflective layer 50 in the first light-emitting device 11 that is proximate to the second light-emitting device 12, and then reflected by the second reflective layer 60 so that a large proportion of the light can be emitted from the portion of the first light-emitting device 11 that is not blocked by the second light-emitting device 12, thereby improving the light output efficiency and avoiding the problem of color crosstalk.

It will be noted that a material of the second reflective layer 60 may be the same as or different from a material of the first reflective layer 50. For example, the second reflective layer 60 and the first reflective layer 50 are both metal reflective layers, and embodiments of the present disclosure are not specifically limited herein.

In some embodiments, referring to FIGS. 12 and 13, a surface of the first reflective layer 50 proximate to the base 110 and/or a surface of the first reflective layer 50 away from the base 110 are subject to a texturizing treatment, so as to cause at least one of the above surfaces of the first reflective layer 50 to be rough. Here, a surface of the first reflective layer 50 proximate to the base 110 may be referred to as a main surface 50a, and a surface of the first reflective layer 50 away from the base 110 may be referred to as a main surface 50b. In this way, the roughness of the main surface can produce a relatively good scattering effect, so that the light irradiated thereon can be emitted after relatively few reflections, reducing the loss of light, and improving the light output efficiency.

In some examples, as shown in FIGS. 18, 21 and 22, the first light-emitting device 11 includes a first reflective layer 50, the second light-emitting device 12 includes no first reflective layer 50, and the third light-emitting device 13 includes another first reflective layer 50.

Two main surfaces 50a, 50b of the first reflective layer 50 described above are subjected to a texturizing treatment, so that the two main surfaces 50a, 50b of the first reflective layer 50 are rough.

In some other examples, as shown in FIGS. 14, 19, 20 and 23, the first light-emitting device 11 includes no first reflective layer 50, the second light-emitting device 12 includes no first reflective layer 50, and the third light-emitting device 13 includes two first reflective layers 50.

Two main surfaces 50a, 50b of the first reflective layer 50 described above are subjected to a texturizing treatment, so that the two main surfaces 50a, 50b of the first reflective layer 50 are rough.

In yet some other examples, as shown in FIGS. 12, 18, 20 and 20, the first light-emitting device 11 includes a first reflective layer 50, the second light-emitting device 12 includes two first reflective layers 50, and the third light-emitting device 13 includes another first reflective layer 50.

A main surface 50a of the first reflective layer 50 of the above-described first light-emitting device 11 proximate to the base 110 is subjected to texturizing treatment, so that the main surface 50a of the first reflective layer 50 of the first light-emitting device 11 proximate to the base 110 is rough.

Two main surfaces 50b, 50b, opposite to each other, of the two first reflective layers 50 in the above-described second light-emitting device 12 are subjected to a texturizing treatment, so that the two main surfaces 50b, 50b, opposite to each other, of the two first reflective layers 50 are rough.

A main surface 50b of the first reflective layer 50 of the above-described third light-emitting device 13 away from the base 110 is subjected to texturizing treatment, so that the main surface 50b of the first reflective layer 50 of the third light-emitting device 13 away from the base 110 is rough.

Here, the surface roughness of the above-described rough main surface is in a range of 10 nm to 100 nm, inclusive. That is, the surface roughness of at least one of the main surfaces of the first reflective layer 50 is in a range of 10 nm to 100 nm, inclusive. For example, at least one of the main surfaces of the first reflective layer 50 has a surface roughness of any one of 10 nm, 20 nm, 30 nm, 40 nm, 50 nm, 55 nm, 60 nm, 70 nm, 80 nm, 90 nm, and 100 nm. By way of example, the surface roughness of at least one of the main surfaces of the first reflective layer 50 is in a range of 50 nm to 60 nm, inclusive.

In addition, as shown in FIG. 12, a main surface 60b of the second reflective layer 60 away from the base 110 described above may also be subjected to a texturizing treatment, so that the main surface 60b of the second reflective layer 60 away from the base 110 is rough in order to produce a relatively good scattering effect, so that the light may be emitted after relatively few times of reflections, reducing the light loss and increasing the light output efficiency.

Moreover, the surface roughness of the rough main surface 60b of the second reflective layer 60 away from the base 110 is in a range of 10 nm to 100 nm, inclusive. For example, the surface roughness of the rough main surface 60b of the second reflective layer 60 away from the base 110 has a surface roughness of any one of 10 nm, 20 nm, 30 nm, 40 nm, 50 nm, 55 nm, 60 nm, 70 nm, 80 nm, 90 nm, and 100 nm. Byway of example, the surface roughness of the rough main surface 60b of the second reflective layer 60 away from the base 110 is in a range of 50 nm to 60 nm, inclusive.

In some embodiments, as shown in FIGS. 12 to 23, an orthographic projection of the light-emitting layer 42 on the base 110 substantially coincides with an orthographic projection of the second semiconductor layer 43 on the base 110. An area of the first semiconductor layer 41 is greater than an area of the light-emitting layer 42, and the orthographic projection of the light-emitting layer 42 on the base 110 lies within a range of an orthographic projection of the first the semiconductor layer 41 is on the base 110.

The first semiconductor layer 41 includes a first portion 411 and a second portion 412. The first portion 411 is a portion of the first semiconductor layer 41 that is overlapped with the light-emitting layer 42, and the second portion 412 is a portion of the first semiconductor layer 41 that is non-overlapping with the light-emitting layer 42.

On this basis, as shown in FIGS. 12 to 17, the above-mentioned light-emitting diode 21 further includes a plurality of first bonding pads 111, a plurality of second bonding pads 112, a plurality of first transfer electrodes 113, a plurality of second transfer electrodes 113, and a plurality of conductive lines 810.

As shown in FIGS. 12 to 17, the plurality of first bonding pads 111 and the plurality of second bonding pads 112 are all provided on the base 110. A first transfer electrode 113 is provided on a second semiconductor layer 43 of a light-emitting device 10, and a second transfer electrode 114 is provided on a second portion 412 of a first semiconductor layer 41 of this light-emitting device 10.

As shown in FIGS. 12 to 17, the plurality of conductive lines 810 includes anode conductive line(s) 811 and cathode conductive line(s) 812. Of an anode conductive line 811, one end is connected to a first bonding pad 111, and the other end is connected to a first transfer electrode 113; and of the cathode conductive line 812, one end is connected to a second bonding pad 112, and the other end is connected to the second transfer electrode 114.

In this case, good insulation can be formed between the light-emitting stacked layer 40 and both the anode conductive line 811 and the cathode conductive line 812, and it is convenient for the anode conductive line 811 and the cathode conductive line 812 to be connected to the first transfer electrode 113 and the second transfer electrode 114, respectively.

In some examples, referring to FIGS. 8 and 10, and FIGS. 15 to 17, the above-mentioned light-emitting diode 21 includes a first conductive layer 81 and a first barrier layer 91.

Here, the first barrier layer 91 is provided between the first conductive layer 81 and the plurality of light-emitting devices 10. And, the first barrier layer 91 exposes the first transfer electrode 113 and the second transfer electrode 114, so as to facilitate the connection of the anode conductive line 811 to the first transfer electrode 113, and the cathode conductive line 812 to the second transfer electrode 114.

In this case, the plurality of conductive lines 810 are located in the first conductive layer 81, and orthographic projections of the plurality of conductive lines 810 on the base 110 are staggered. Arranged in this way, the above-mentioned light-emitting diode 21 only needs to be provided with one conductive layer and one barrier layer, with a simple structure and low manufacturing cost.

A material of the above-described first conductive layer 81 includes a metal and/or a metal oxide. By way of example, the material of the first electrically conductive layer 81 includes at least one of silver, aluminum, copper, or iron. For example, the material of the first conductive layer 81 is copper.

A material of the above-described first barrier layer 91 may include an inorganic insulating material. By way of example, the material of the first barrier layer 91 includes at least one of silicon nitride, silicon nitride oxide, or silicon oxide. For example, the material of the first barrier layer 91 is silicon dioxide.

In some other examples, referring to FIGS. 9, 11, and 12 to 14, the light-emitting diode 21 includes a second conductive layer 82, a third conductive layer 83, a fourth conductive layer 84, a second barrier layer 92, a third barrier layer 93, and a fourth barrier layer 94.

As shown in FIGS. 12, 13, and 14, a conductive line 810 connected to the first light-emitting device 11 is located in the second conductive layer 82, a conductive line 810 connected to the second light-emitting device 12 is located in the third conductive layer 83, and a conductive line 810 connected to the third light-emitting device 13 is located in the fourth conductive layer 84.

As shown in FIGS. 12, 13, and 14, the second barrier layer 92 is provided between the second conductive layer 82 and the plurality of light-emitting devices 10, and the second barrier layer 92 exposes all of the first transfer electrodes 113 and the second transfer electrodes 114; the third barrier layer 93 is provided between the second conductive layer 82 and the third conductive layer 83, and the third barrier layer 93 exposes the first transfer electrodes 113 and the second transfer electrodes 114 that are located on the second light-emitting device 12 and the third light-emitting device 13; and the fourth barrier layer 94 is provided between the third conductive layer 83 and the fourth conductive layer 84, and the fourth barrier layer 94 exposes the first transfer electrode 113 and the second transfer electrode 114 that are located on the third light-emitting device 13.

In this case, as shown in FIGS. 9 and 11, the above-described first bonding pads 111, second bonding pads 112, first transfer electrodes 113, and second transfer electrodes 114 may be arranged, for example, along a first direction X, and the plurality of conductive lines 810 extends along the first direction X. Arranged in this way, the first bonding pads 111 and the second bonding pads 112 of the light-emitting diode 21 are arranged in a straight line, which is conducive to reducing the difficulty of the circuit design of the array substrate 101 and facilitating the connection of the light-emitting diode 21 to the array substrate 101.

Materials of the second barrier layer 92, the third barrier layer 93, and the fourth barrier layer 94 described above may each include an inorganic insulating material. By way of example, the materials of the second barrier layer 92, the third barrier layer 93, and the fourth barrier layer 94 each include at least one of silicon nitride, silicon nitride oxide, or silicon oxide. For example, the materials of the second barrier layer 92, the third barrier layer 93, and the fourth barrier layer 94 are all silicon dioxide.

Materials of the second conductive layer 82, the third conductive layer 83, and the fourth conductive layer 84 described above each include a metal and/or a metal oxide. By way of example, the materials of the second conductive layer 82, the third conductive layer 83, the fourth conductive layer 84 each include at least one of silver, aluminum, copper, or iron. For example, the materials of the second conductive layer 82, the third conductive layer 83, the fourth conductive layer 84 are all copper.

It can be understood that there are various driving methods for the light-emitting diode 21 addressed above.

In some examples, as shown in FIG. 6, the light-emitting substrate 210 includes a plurality of driving units 211 arranged in an array, each driving unit 211 including a plurality of light-emitting diodes 21 connected in series and/or in parallel.

By way of example, as shown in FIG. 6, each driving unit 211 includes four light-emitting diodes 21 sequentially connected in series. Of course, each driving unit 211 may also include four, five, seven, or eight light-emitting diodes 21, and the connection of these light-emitting diodes 21 in the driving unit 211 is not limited to series connection, but may also be connected in parallel, and embodiments of the present disclosure are not limited thereto.

The above-mentioned microchip 22 may, for example, be a driving chip to drive a plurality of light-emitting diodes 21 to emit light. Here, a microchip 22 may only drive a plurality of light-emitting diodes 21 in a corresponding driving unit 211; alternatively, a microchip 22 may drive a plurality of light-emitting diodes 21 in multiple driving units 211, separately.

By way of example, as shown in FIG. 6, every four driving units 211 are electrically connected to a microchip 22, so this microchip 22 is electrically connected to a plurality of light-emitting diodes 21 in these four driving units 211 separately, so as to separately drive the plurality of light-emitting diodes 21 in these four driving units 211 to emit light.

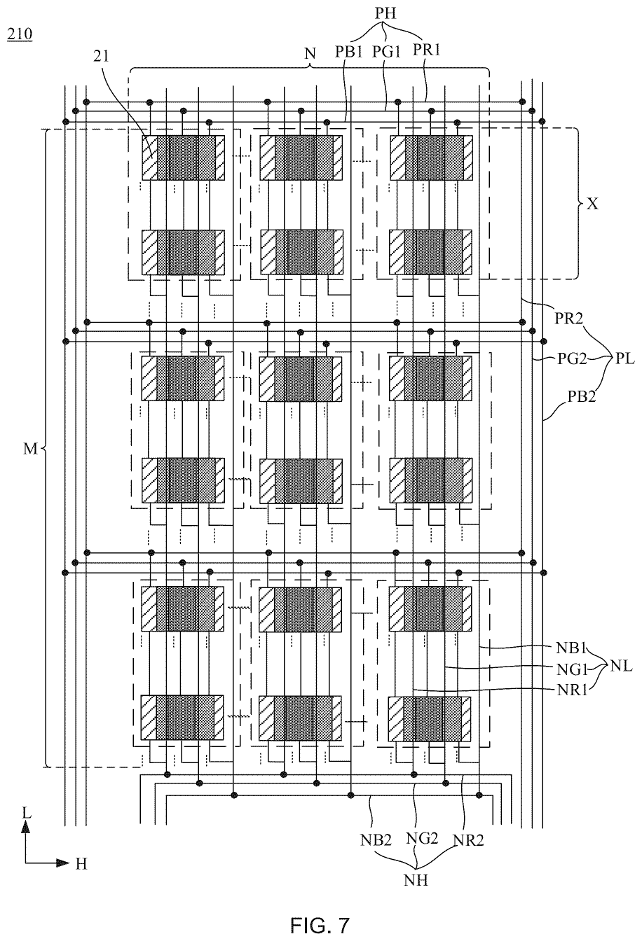

In some other examples, as shown in FIG. 7, all of the light-emitting diodes 21 in the light-emitting substrate 210 are arranged in M rows and N columns (M×N).

In each column of light-emitting diodes 21, starting from the first light-emitting diode 21, every adjacent X light-emitting diodes 21 are connected in series in sequence, where 1≤X≤M, and X is an integer. Here, the X light-emitting diodes 21 connected in series are defined as a group of light-emitting diodes 21.

It will be noted that the adjacent X light-emitting diodes 21 connected in series in sequence means that in the adjacent X light-emitting diodes 21, all first light-emitting devices 11 are connected in series in sequence, all second light-emitting devices 12 are connected in series in sequence, and all third light-emitting devices 13 are connected in series in sequence.

On this basis, in the above-mentioned M×N light-emitting diodes 21, light-emitting devices 10 with a same light-emitting color, which are included in multiple groups of light-emitting diodes 21, are arranged in parallel.

By way of example, as shown in FIG. 7, every X row of light-emitting diodes 21 corresponds to a group of row positive electrode wires PH extending along a row direction H, and each group of row positive electrode wires PH includes a first row positive electrode wire PR1, a second row positive electrode wire PG1, and a third row positive electrode wire PB1; and, in each group of light-emitting diodes 21, a plurality of first light-emitting devices 11 connected in series, a plurality of second light-emitting devices 12 connected in series, and a plurality of third light-emitting devices 13 connected in series are connected to a first row positive electrode wire PR1, a second row positive electrode wire PG1, and a third row positive electrode wire PB1, respectively.

Here, multiple row positive electrode wires PH corresponding to light-emitting devices 10 with the same light-emitting color in the M×N light-emitting diodes 21 extend to the outer side of the M×N light-emitting diodes 21, and are connected to a same column positive electrode wire PL extending along a column direction L.

For example, the first row positive electrode wire PR1 is connected to the first column positive electrode wire PR2, the second row positive electrode wire PG1 is connected to the second column positive electrode wire PG2, and the third row positive electrode wire PB1 is connected to the third column positive electrode wire PB2.

In addition, in each column of light-emitting diodes 21, a plurality of light-emitting devices 10 with a same light-emitting color correspond to a column negative electrode wire NL; and for multiple column negative electrode wires NL corresponding to light-emitting devices 10 with the same light-emitting color in multiple columns of light-emitting diodes 21, these multiple column negative electrode wires NL are connected to a same row negative electrode wire NH.

For example, the column negative electrode wires NL may include a plurality of first column negative electrode wires NR1, a plurality of second column negative electrode wires NG1, and a plurality of third column negative electrode wires NB1; the row negative electrode wires NH include a first row negative electrode wire NR2, a second row negative electrode wire NG2, and a third row negative electrode wire NB2; and the plurality of first column negative electrode wires NR1 are connected to the first row negative electrode wire NR2, the plurality of second column negative electrode wires NG1 are connected to the second row negative electrode alignment NG2, and the plurality of third column negative electrode wires NB1 are connected to the third row negative electrode wire NB2.

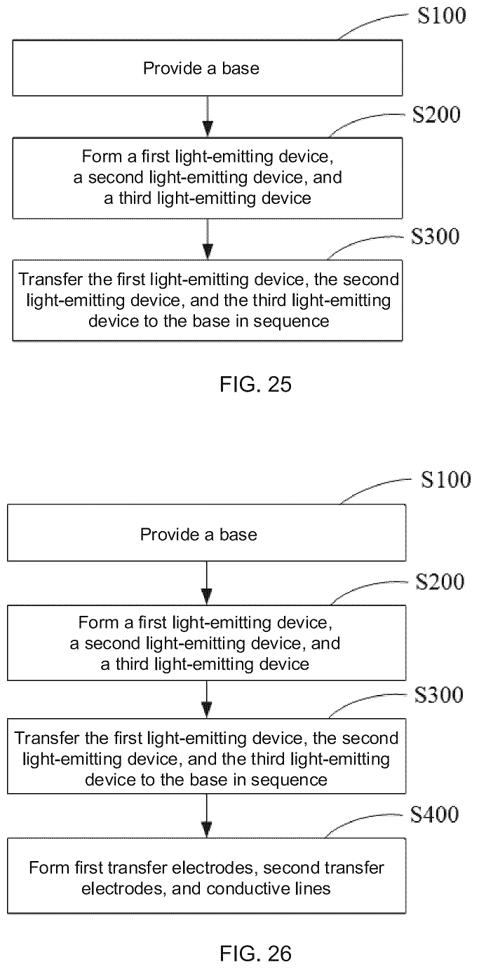

Referring to FIG. 25, some embodiments of the present disclosure provide a manufacturing method for a light-emitting diode 21, and the manufacturing method includes the following steps S100 to S300.

In S100, as shown in FIG. 12, a base 110 is provided.

In the above step, the base 110 plays a supporting role, allowing the subsequently formed light-emitting device 10 to be transferred thereon, so that the formed light-emitting diode 21 has high stability and reliability.

It will be noted that the base 110 may be provided with a plurality of first bonding pads 111 and a plurality of second bonding pads 112. A material of the base 110 may be referred to above, and the embodiments of the present disclosure will not be repeated herein.

In S200, a first light-emitting device 11, a second light-emitting device 12, and a third light-emitting device 13 are formed as shown in FIGS. 18 to 23.

In the above step, an area of the first light-emitting device 11 is greater than an area of the second light-emitting device 12, and the area of the second light-emitting device 12 is greater than an area of the third light-emitting device 13.

It will be noted that the structures of the first light-emitting device 11, the second light-emitting device 12, and the third light-emitting device 13 can be referred to above, and the embodiments of the present disclosure will not be repeated herein.

By way of example, in a process of forming the second light-emitting device 12, first, a buffer layer 47, a first semiconductor layer 41, a light-emitting layer 42, a second semiconductor layer 43, a first electrode 48, and a first reflective layer 50 may be sequentially superimposed on an underlayer 46; then, the underlayer 46 is removed; and finally, another first reflective layer 50 is formed on a side of the buffer layer 47 away from the first electrode 48.

It will be noted that the respective materials of the underlayer 46, the buffer layer 47, the first semiconductor layer 41, the light-emitting layer 42, the second semiconductor layer 43, the first electrode 48, and the first reflective layer 50 can be referred to above, and the embodiments of the present disclosure will not be repeated herein.

In S300, as shown in FIGS. 12 to 17, the first light-emitting device 11, the second light-emitting device 12, and the third light-emitting device 13 are transferred to the base 110 in sequence.

In the above step, the first light-emitting device 11 is provided on the base 110, the second light-emitting device 12 is provided on a side of the first light-emitting device 11 away from the base 110, and the third light-emitting device 13 is provided on a side of the second light-emitting device 12 away from the base 110.

It will be noted that in each light-emitting device 11, the first semiconductor layer 41 is closer to the base 110 than the second semiconductor layer 43.

As can be seen from the above, in the manufacturing method of the light-emitting diode 21 provided in some embodiments of the present disclosure, the first reflective layer 50 is formed during the process of forming the first light-emitting device 11, the second light-emitting device 12, and the third light-emitting device 13, and then transferred to the base 110 with the first light-emitting device 11, the second light-emitting device 12, and the third light-emitting device 13, which makes a simple process, and low preparation cost.

In some embodiments, after S300, referring to FIG. 26, the manufacturing method may further include a step S400.

In S400, referring to FIGS. 12 to 17, first transfer electrodes 113, second transfer electrodes 114, and conductive lines 810 are formed.

In some examples, referring to FIGS. 12, 13, and 14, forming the conductive lines 810 in S400 specifically includes: forming a second barrier layer 92, a second conductive layer 82, a third barrier layer 93, a third conductive layer 83, a fourth barrier layer 94, and a fourth conductive layer 84 in sequence; and patterning the second conductive layer 82, the third conductive layer 83, and the fourth conductive layer 84, thereby forming the conductive lines 810.

In some other examples, referring to FIGS. 15, 16 and 17, forming the conductive lines 810 in S400 specifically includes: forming a first barrier layer 91 and a first conductive layer 81 in sequence, and patterning the first conductive layer 81, thereby forming conductive lines 810.

In the description of the present specification, specific features, structures, materials, or characteristics may be combined in any one or more embodiments or examples in a suitable manner.

The foregoing description is only specific embodiments of the present disclosure, but the scope of protection of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

What is claimed is:

1. A light-emitting diode, comprising:
a base; and
a plurality of light-emitting devices, including a first light-emitting device, a second light-emitting device, and a third light-emitting device that are stacked on the base in sequence, wherein an area of the first light-emitting device is greater than an area of the second light-emitting device, and the area of the second light-emitting device is greater than an area of the third light-emitting device; and a light-emitting color of the first light-emitting device, a light-emitting color of the second light-emitting device, and a light-emitting color of the third light-emitting device are three primary colors;
wherein each of the plurality of light-emitting devices includes a light-emitting stacked layer; and
in two adjacent light-emitting devices of the plurality of light-emitting devices, at least one light-emitting device further includes a first reflective layer, wherein the first reflective layer is provided between a light-emitting stacked layer of the light-emitting device to which the first reflective layer belongs and another light-emitting device, and the first reflective layer covers a first region and exposes at least a portion of a second region, the first region being a region where the two adjacent light-emitting devices overlap with each other, and the second region being a region where the two adjacent light-emitting devices are non-overlapping with each other.

2. The light-emitting diode according to claim 1, wherein the at least one light-emitting device in the two adjacent light-emitting devices includes the first light-emitting device and the third light-emitting device, wherein
the first light-emitting device includes a first reflective layer, the first reflective layer being provided on a side of a light-emitting stacked layer of the first light-emitting device away from the base; and
the third light-emitting device includes another first reflective layer, the first reflective layer being provided on a side of a light-emitting stacked layer of the third light-emitting device proximate to the base.

3. The light-emitting diode according to claim 1, wherein the at least one light-emitting device in the two adjacent light-emitting devices includes the second light-emitting device, wherein
the second light-emitting device includes two first reflective layers, the two first reflective layers being provided on two sides opposite to each other of a light-emitting stacked layers of the second light-emitting device.

4. The light-emitting diode according to claim 1, wherein the first reflective layer includes a distributed Bragg reflective film layer, the distributed Bragg reflective film layer including a plurality of first medium layers and a plurality of second medium layers, wherein
the plurality of first medium layers and the plurality of second medium layers are alternately stacked; and a difference between a refractive index of the first medium layers and a refractive index of the second medium layers is greater than or equal to 0.3.

5. The light-emitting diode according to claim 4, wherein the refractive index of the first medium layers is in a range of 1.8 to 2.4, inclusive; and the refractive index of the second medium layers is in a range of 1.2 to 1.8, inclusive.

6. The light-emitting diode according to claim 1, wherein the first reflective layer includes a metal reflective layer, a reflectivity of the metal reflective layer being greater than or equal to 85%.

7. The light-emitting diode according to claim 1, wherein of a surface of the first reflective layer proximate to the base or a surface of the first reflective layer away from the base, at least one has surface roughness in a range of 10 nm to 100 nm, inclusive.

8. The light-emitting diode according to claim 1, wherein the first light-emitting device further includes:
a second reflective layer provided between a light-emitting stacked layer of the first light-emitting device and the base, wherein an orthographic projection of the light-emitting stacked layer of the first light-emitting device on the base substantially coincides with an orthographic projection of the second reflective layer on the base, or lies within a range of the orthographic projection of the second reflective layer on the base.

9. The light-emitting diode according to claim 1, wherein the light-emitting stacked layer includes:
a first semiconductor layer;
a light-emitting layer provided on a side of the first semiconductor layer, wherein an area of the light-emitting layer is less than an area of the first semiconductor layer, and an orthographic projection of the light-emitting layer on the base lies within a range of an orthographic projection of the first the semiconductor layer is on the base; and
a second semiconductor layer provided on a side of the light-emitting layer away from the first semiconductor layer, wherein an orthographic projection of the second semiconductor layer on the base substantially coincides an orthographic projection of the light-emitting layer on the base.

10. The light-emitting diode according to claim 9, wherein the first semiconductor layer includes a first portion and a second portion, the first portion being a portion of the first semiconductor layer that is overlapped with the light-emitting layer, and the second portion being a portion of the first semiconductor layer that is non-overlapping with the light-emitting layer;
the light-emitting substrate further comprises:
a plurality of first bonding pads provided on the base;
a plurality of second bonding pads provided on the base;
a plurality of first transfer electrodes, a first transfer electrode of the plurality of first transfer electrodes being provided on a second semiconductor layer of a light-emitting device of the plurality of light-emitting devices;
a plurality of second transfer electrodes, a second transfer electrode of the plurality of second transfer electrodes being provided on a second portion of a first semiconductor layer of the light-emitting device of the plurality of light-emitting devices; and
a plurality of conductive lines including anode conductive lines and cathode conductive lines, wherein of an anode conductive line of the anode conductive lines, one end is connected to a first bonding pad of the plurality of first bonding pads, and an other end is connected to the first transfer electrode; and of a cathode conductive line of the cathode conductive lines, one end is connected to a second bonding pad of the plurality of second bonding pads, and an other end is connected to the second transfer electrode.

11. The light-emitting diode according to claim 10, wherein orthographic projections of the plurality of conductive lines on the base are staggered; the light-emitting diode further comprises:
a first conductive layer, the plurality of conductive lines being located in the first conductive layer; and
a first barrier layer provided between the first conductive layer and the plurality of light-emitting devices, and the first barrier layer exposing the first transfer electrodes and the second transfer electrodes.

12. The light-emitting diode according to claim 10, wherein the first bonding pads, the first transfer electrodes, the second bonding pads, and the second transfer electrodes are arranged along a same direction, and the plurality of conductive lines extend along the same direction; the light-emitting diode further comprises:
a second conductive layer, conductive lines connected to the first light-emitting device being located in the second conductive layer;
a third conductive layer, conductive lines connected to the second light-emitting device being located in the third conductive layer;
a fourth conductive layer, conductive lines connected to the third light-emitting device being located in the fourth conductive layer;
a second barrier layer provided between the second conductive layer and the plurality of light-emitting devices, and the second barrier layer exposing the first transfer electrodes and the second transfer electrodes;
a third barrier layer provided between the second conductive layer and the third conductive layer, and the third barrier layer exposing first transfer electrodes and second transfer electrodes that are located on the second light-emitting device and the third light-emitting device; and
a fourth barrier layer provided between the third conductive layer and the fourth conductive layer, and the fourth barrier layer exposing a first transfer electrode and a second transfer electrode that are located on the third light-emitting device.

13. The light-emitting diode according to claim 1, wherein a boundary of an orthographic projection of the first light-emitting device on the base, a boundary of an orthographic projection of the second light-emitting device on the base, and a boundary of an orthographic projection of the third light-emitting device on the base are in a same shape; and
the boundary of the orthographic projection of the first light-emitting device on the base and the boundary of the orthographic projection of the second light-emitting device on the base have a gap therebetween; and the boundary of the orthographic projection of the second light-emitting device on the base and the boundary of the orthographic projection of the third light-emitting device on the base have another gap therebetween.

14. The light-emitting diode according to claim 13, wherein the orthographic projection of the first light-emitting device on the base, the orthographic projection of the second light-emitting device on the base, and the orthographic projection of the third light-emitting device on the base are each substantially in a shape of a circle or a polygon.

15. The light-emitting diode according to claim 14, wherein a geometric center of the orthographic projection of the first light-emitting device on the base, a geometric center of the orthographic projection of the second light-emitting device on the base, and a geometric center of the orthographic projection of the third light-emitting device on the base substantially coincide.

16. The light-emitting diode according to claim 1, wherein the light-emitting color of the first light-emitting device is red; and the light-emitting color of one of the second light-emitting device and the third light-emitting device is blue, and the light-emitting color of the other is green.

17. A manufacturing method for a light-emitting diode, comprising:
providing a base;
forming a first light-emitting device, a second light-emitting device, and a third light-emitting device, an area of the first light-emitting device being greater than an area of the second light-emitting device, and the area of the second light-emitting device being greater than an area of the third light-emitting device; and
transferring the first light-emitting device, the second light-emitting device, and the third light-emitting device to the base in sequence, the first light-emitting device being provided on the base, the second light-emitting device being provided on a side of the first light-emitting device away from the base, and the third light-emitting device being provided on a side of the second light-emitting device away from the base;
wherein each of the plurality of light-emitting devices includes a light-emitting stacked layer; and
in two adjacent light-emitting devices of the plurality of light-emitting devices, at least one light-emitting device further includes a first reflective layer, wherein the first reflective layer is provided between a light-emitting stacked layer of the light-emitting device to which the first reflective layer belongs and another light-emitting device, and the first reflective layer covers a first region and exposes at least a portion of a second region, the first region being a region where the two adjacent light-emitting devices overlap with each other, and the second region being a region where the two adjacent light-emitting devices are non-overlapping with each other.

18. A light-emitting substrate, comprising:
an array substrate; and
the light-emitting diode as claimed in claim 1, the light-emitting diode being provided on the array substrate.

19. A backlight module, comprising:
the light-emitting substrate as claimed in claim 18, the light-emitting substrate having a light exit side and a non-light exit side opposite to each other; and
a plurality of optical film sheets provided on the light exit side of the light-emitting substrate.

20. A display device, comprising:
the backlight module as claimed in claim 19; and
a display panel provided on a side, away from the light-emitting substrate, of the plurality of optical film sheets in the backlight module.
